(19) United States
(12) Patent Application Publication
(10) Pub. No.: US 2025/0261512 A1
(43) Pub. Date: Aug. 14, 2025

(54) DISPLAY DEVICE

(71) Applicant: Samsung Display Co., LTD., Yongin-si (KR)

(72) Inventors: Sung Hwan KIM, Yongin-si (KR); Dae Hyun KIM, Yongin-si (KR)

(73) Assignee: Samsung Display Co., LTD, Yongin-si (KR)

(21) Appl. No.: 19/015,296

(22) Filed: Jan. 9, 2025

(30) Foreign Application Priority Data
Feb. 13, 2024 (KR) 10-2024-0020467

(51) Int. Cl. H10K 59/121; H10K 59/131

(52) U.S. Cl. CPC H10K 59/1213; H10K 59/131

(57) ABSTRACT

A display device comprises a light emitting element disposed on a substrate, a first transistor controlling a driving current supplied to the light emitting element, a second transistor supplying a data voltage to a source electrode of the first transistor, and a third transistor electrically connecting a drain electrode of the first transistor to a gate electrode of the first transistor. The second transistor comprises a semiconductor region disposed in a first active layer on the substrate and a gate electrode disposed in a first gate layer on the first active layer. The first transistor comprises a semiconductor region disposed in a second active layer on the first gate layer, a gate electrode disposed in a second gate layer on the second active layer, and a bias electrode disposed in the first active layer.

### CROSS-REFERENCE TO RELATED APPLICATION(S)

This application claims priority to and benefits of Korean Patent Application No. 10-2024-0020467 under 35 U.S.C. § 119 filed on Feb. 13, 2024, in the Korean Intellectual Property Office, the entire contents of which are incorporated herein by reference.

### BACKGROUND

### 1. Technical Field

The disclosure relates to a display device.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions. The display device may be a flat panel display device such as a liquid crystal display device, a field emission display device and an organic light emitting display device. Among the flat panel display devices, in the light emitting display device, since each of pixels of a display panel may include a light emitting element capable of emitting light by itself, an image can be displayed without a backlight unit providing light to the display panel.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a display device capable of reducing the number of contact holes of a pixel circuit and readily designing a high-resolution pixel.

However, aspects of the disclosure are not restricted to the ones set forth herein. The above and other aspects of the disclosure will become more apparent to one of ordinary skill in the art to which the disclosure pertains by referencing the detailed description of the disclosure given below.

According to an embodiment, a display device may include a light emitting element disposed on a substrate; a first transistor controlling a driving current supplied to the light emitting element; a second transistor supplying a data voltage to a source electrode of the first transistor; and a third transistor electrically connecting a drain electrode of the first transistor to a gate electrode of the first transistor. The second transistor comprises a semiconductor region disposed in a first active layer on the substrate and a gate electrode disposed in a first gate layer on the first active layer. The first transistor comprises a semiconductor region disposed in a second active layer on the first gate layer, a gate electrode disposed in a second gate layer on the second active layer, and a bias electrode disposed in the first active layer.

The bias electrode of the first transistor may be electrically connected to the source electrode of the first transistor and may overlap the semiconductor region and the gate electrode of the first transistor.

The first active layer may comprise a silicon-based semiconductor region and the second active layer may comprise an oxide-based semiconductor region.

The display device may further comprise a capacitor electrically connected between the gate electrode of the first transistor and a first electrode of the light emitting element, and a fourth transistor electrically connecting an initialization voltage line supplying an initialization voltage to the first electrode of the light emitting element.

The display device may further comprise a fifth transistor electrically connecting a diving voltage line supplying a driving voltage to the drain electrode of the first transistor, and a sixth transistor electrically connecting the source electrode of the first transistor to the first electrode of the light emitting element.

The bias electrode of the first transistor may be electrically connected to a source electrode of the sixth transistor.

According to an embodiment, a display device may include a light emitting element disposed on a substrate; a first transistor controlling a driving current supplied to the light emitting element; a second transistor supplying a data voltage to a source electrode of the first transistor; a third transistor electrically connecting a drain electrode of the first transistor to a gate electrode of the first transistor; and a capacitor electrically connected between the gate electrode of the first transistor and a first electrode of the light emitting element. The first transistor comprises a semiconductor region including an oxide, a drain electrode and a source electrode doped into n-type, and a bias electrode doped into p-type.

The bias electrode of the first transistor and a semiconductor region of the second transistor may be disposed on a same layer.

The second transistor may comprise a source electrode and a drain electrode doped into p-type, and the third transistor may comprise a drain electrode and a source electrode doped into n-type.

The bias electrode of the first transistor may be electrically connected to the source electrode of the first transistor and may overlap the semiconductor region and the gate electrode of the first transistor.

The display device may further comprise a fourth transistor electrically connecting an initialization voltage line supplying an initialization voltage and a first electrode of the light emitting element.

The display device may further comprise a fifth transistor electrically connecting a driving voltage line supplying a driving voltage to the drain electrode of the first transistor, and a sixth transistor electrically connecting the source electrode of the first transistor to the first electrode of the light emitting element.

The fourth transistor may comprise a drain electrode and a source electrode doped into n-type, and each of fifth transistor and sixth transistor may comprise a source electrode and a drain electrode doped into p-type.

According to an embodiment, a display device may include a first active layer disposed on a substrate and comprising a silicon-based semiconductor region; a first gate layer disposed on the first active layer; a second active layer disposed on the first gate layer and comprising an oxide-based semiconductor region; a second gate layer disposed on the second active layer; a first transistor comprising a semiconductor region disposed in the second active layer; a gate electrode disposed in the second gate layer; and a bias electrode disposed in the first active layer; a second transistor comprising a semiconductor region disposed in the first active layer and supplying a data voltage to a source electrode of the first transistor; and a third transistor comprising a semiconductor region disposed in the second active layer and electrically connecting a drain electrode of the first transistor to the gate electrode of the first transistor.

The display device may further comprise a third gate layer disposed on the second gate layer, and a capacitor comprising a first capacitor electrode disposed in the second gate layer to comprise the gate electrode of the first transistor and a second capacitor electrode disposed in the third gate layer.

The display device may further comprise a first source metal layer disposed on the third gate layer, a second source metal layer disposed on the first source metal layer, a first connection electrode disposed in the first source metal layer electrically connected to a source electrode of the second transistor, and a data line disposed in the second source metal layer to supply a data voltage to the first connection electrode.

The display device may further comprise a second connection electrode disposed in the first source metal layer to electrically connect the source electrode of the first transistor, the bias electrode of the first transistor, and a drain electrode of the second transistor.

The display device may further comprise a third connection electrode disposed in the first source metal layer to electrically connect the gate electrode of the first transistor and a source electrode of the third transistor.

The display device may further comprise a light emitting element disposed on the second source metal layer, a driving voltage line disposed in the first source metal layer and supplying a driving voltage, an initialization voltage line disposed in the third gate layer and supplying an initialization voltage, a fourth transistor comprising a semiconductor region disposed in the second active layer and electrically connecting the initialization voltage line to a first electrode of the light emitting clement, a fifth transistor comprising a semiconductor region disposed in the first active layer and electrically connecting the driving voltage line to the drain electrode of the first transistor, and a sixth transistor comprising a semiconductor region disposed in the first active layer and electrically connecting the source electrode of the first transistor to the first electrode of the light emitting element.

The display device may further comprise a fourth connection electrode disposed in the first source metal layer and electrically connecting the drain electrode of the first transistor, a drain electrode of the third transistor, and a drain electrode of the fifth transistor, and a fifth connection electrode disposed in the first source metal layer and electrically connecting the initialization voltage line to a source electrode of the fourth transistor.

In accordance with the display device according to embodiments, as a first transistor may include a bias electrode disposed on a first active layer and a semiconductor area disposed on a second active layer, the number of contact holes of a pixel circuit may be reduced and a high-resolution pixel may be readily designed.

The effects of the disclosure are not limited to the aforementioned effects, and various other effects are included in the specification.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view showing a display device according to an embodiment;

FIG. 2 is a schematic cross-sectional view illustrating a display device according to an embodiment;

FIG. 3 is a schematic plan view illustrating a display unit of a display device according to an embodiment;

FIG. 4 is a block diagram illustrating a display panel and a display driver according to an embodiment;

FIG. 5 is a schematic diagram of an equivalent circuit of a pixel of a display device according to an embodiment;

FIG. 6 is a waveform diagram of signals supplied to the pixel shown in FIG. 5;

FIG. 7 is a plan diagram illustrating a pixel shown in FIG. 5;

FIG. 8 is a diagram illustrating some layers of the plan diagram of FIG. 7;

FIG. 9 is a diagram illustrating some other layers of the plan diagram of FIG. 7;

FIG. 10 is a diagram illustrating yet some other layers of the plan diagram of FIG. 7; and

FIG. 11 is a schematic cross-sectional view taken along line I-I′ of FIG. 7.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods employing one or more of the disclosure disclosed herein. It is apparent, however, that various embodiments may be practiced without these specific details or with one or more equivalent arrangements. In other instances, structures and devices are shown in block diagram form in order to avoid unnecessarily obscuring various embodiments. Further, various embodiments may be different, but do not have to be exclusive nor limit the disclosure. For example, specific shapes, configurations, and characteristics of an embodiment may be used or implemented in other embodiments without departing from the disclosure.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, ZZ, or the like. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein should be interpreted accordingly.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not necessarily intended to be limiting.

As customary in the field, an embodiment is described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (for example, microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (for example, one or more programmed microprocessors and associated circuitry) to perform other functions. Also, each block, unit, part, and/or module of an embodiment may be physically separated into two or more interacting and discrete blocks, units, parts, and/or modules without departing from the scope of the disclosure. Further, the blocks, units, parts, and/or modules of an embodiment may be physically combined into more complex blocks, units, parts, and/or modules without departing from the scope of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, detailed embodiments of the disclosure is described with reference to the accompanying drawings.

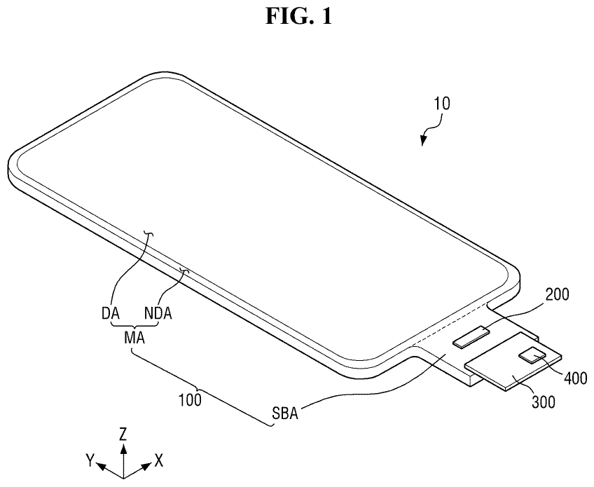

FIG. 1 is a schematic perspective view showing a display device according to an embodiment.

Referring to FIG. 1, a display device 10 may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like within the spirit and the scope of the disclosure. For example, the display device 10 may be applied as a display unit of a television, a laptop, a monitor, a billboard, or an Internet-of-Things (IoT) device. For another example, the display device 10 may be applied to wearable devices such as a smart watch, a watch phone, a glasses type display, or a head mounted display (HMD).

The display device 10 may have a planar shape similar to a quadrilateral shape. For example, the display device 10 may have a shape similar to a quadrilateral shape, in plan view, having short sides in an X-axis direction and long sides in a Y-axis direction. The corner where the short side in the X-axis direction and the long side in the Y-axis direction meet may be rounded to have a selectable curvature or may be right-angled. The planar shape of the display device 10 is not limited to a quadrilateral shape, and may be formed in a shape similar to another polygonal shape, a circular shape, or elliptical shape.

The display device 10 may include a display panel 100, a display driver 200, a circuit board 300, and a touch driver 400.

The display panel 100 may include a main region MA and a sub-region SBA.

The main region MA may include a display area DA including pixels displaying an image and a non-display area NDA disposed around the display area DA. The display area DA may emit light from a plurality of emission areas or a plurality of opening areas. For example, the display panel 100 may include a pixel circuit including switching elements, a pixel defining layer defining an emission area or an opening area, and a self-light emitting element.

For example, the self-light emitting element may include at least one of an organic light emitting diode (LED) including an organic light emitting layer, a quantum dot LED including a quantum dot light emitting layer, an inorganic LED including an inorganic semiconductor, or a micro LED, but is not limited thereto.

The non-display area NDA may be an area outside the display area DA. The non-display area NDA may be defined as an edge area of the main region MA of the display panel 100. The non-display area NDA may include a scan driver (not illustrated) that supplies scan signals to the scan lines, and fan-out lines (not illustrated) that connect the display driver 200 to the display area DA.

The sub-region SBA may extend from one side or a side of the main region MA. The sub-region SBA may include a flexible material which can be bent, folded or rolled. For example, in case that the sub-region SBA is bent, the sub-region SBA may overlap the main region MA in a thickness direction (Z-axis direction). The sub-region SBA may include the display driver 200 and a pad unit connected to the circuit board 300. Optionally, the sub-region SBA may be omitted, and the display driver 200 and the pad unit may be arranged or disposed in the non-display area NDA.

The display driver 200 may output signals and voltages for driving the display panel 100. The display driver 200 may supply data voltages to data lines. The display driver 200 may supply a power voltage to the power line and may supply a scan control signal to the scan driver. The display driver 200 may be formed as an integrated circuit (IC) and mounted on the display panel 100 by a chip on glass (COG) method, a chip on plastic (COP) method, or an ultrasonic bonding method. For example, the display driver 200 may be disposed in the sub-region SBA, and may overlap the main region MA in the thickness direction (Z-axis direction) by bending of the sub-region SBA. For another example, the display driver 200 may be mounted on the circuit board 300.

The circuit board 300 may be attached to the pad unit of the display panel 100 by using an anisotropic conductive film (ACF). Lead lines of the circuit board 300 may be electrically connected to a pad unit of the display panel 100. The circuit board 300 may be a flexible printed circuit board, a printed circuit board, or a flexible film such as a chip on film.

The touch driver 400 may be mounted on the circuit board 300. The touch driver 400 may be electrically connected to a touch sensing unit of the display panel 100. The touch driver 400 may supply a touch driving signal to a plurality of touch electrodes of the touch sensing unit and may sense an amount of change in capacitance between the plurality of touch electrodes. For example, the touch driving signal may be a pulse signal having a selectable frequency. The touch driver 400 may calculate whether an input is made and input coordinates based on an amount of change in capacitance between the plurality of touch electrodes. The touch driver 400 may be formed of an integrated circuit (IC).

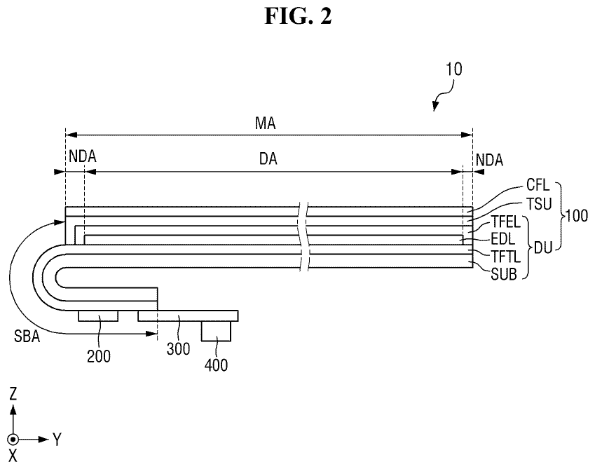

FIG. 2 is a schematic cross-sectional view illustrating a display device according to an embodiment.

Referring to FIG. 2, the display panel 100 may include a display unit DU, a touch sensing unit TSU, and a color filter layer CFL. The display unit DU may include a substrate SUB, a transistor layer TFTL, a light emitting element layer EDL, and an encapsulation layer TFEL.

The substrate SUB may be a base substrate or a base member. The substrate SUB may be a flexible substrate which can be bent, folded or rolled. For example, the substrate SUB may include a polymer resin such as polyimide (PI), but is not limited thereto. For another example, the substrate SUB may include a glass material or a metal material.

The transistor layer TFTL may be disposed on the substrate SUB. The transistor layer TFTL may include a plurality of transistors constituting a pixel circuit of pixels. The transistor layer TFTL may further include scan lines, data lines, power lines, scan control lines, fan-out lines that connect the display driver 200 to the data lines, and lead lines that connect the display driver 200 to the pad unit. Each of the transistors may include a semiconductor region, a source electrode, a drain electrode, and a gate electrode. For example, in case that the scan driver is formed in the non-display area NDA of the display panel 100, the scan driver may include transistors.

The transistor layer TFTL may be disposed in the display area DA, the non-display area NDA, and the sub-region SBA. Transistors, scan lines, data lines, and power lines of each of the pixels of the transistor layer TFTL may be disposed in the display area DA. Scan control lines and fan-out lines of the transistor layer TFTL may be disposed in the non-display area NDA. The lead lines of the transistor layer TFTL may be disposed in the sub-region SBA.

The light emitting element layer EDL may be disposed on the transistor layer TFTL. The light emitting element layer EDL may include a plurality of light emitting elements in which a first electrode, a light emitting layer, and a second electrode are sequentially stacked to emit light, and a pixel defining layer defining pixels. A plurality of light emitting elements of the light emitting element layer EDL may be disposed in the display area DA.

For example, the light emitting layer may be an organic light emitting layer containing an organic material. The light emitting layer may include a hole transporting layer, an organic light emitting layer and an electron transporting layer. In case that the first electrode receives a selectable voltage and the second electrode receives a cathode voltage through the transistors in the transistor layer TFTL, holes may move to the organic light emitting layer through the hole transporting layer and electrons may move to the organic light emitting layer through the electron transporting layer, such that the holes and the electrons combine in the organic light emitting layer to emit light. For example, the first electrode may be an anode electrode or a pixel electrode, while the second electrode may be a cathode electrode or a common electrode. It is, however, to be understood that the disclosure is not limited thereto.

For another example, the plurality of light emitting elements may include a quantum dot light emitting diode including a quantum dot light emitting layer, an inorganic light emitting diode including an inorganic semiconductor, or a micro light emitting diode.

The encapsulation layer TFEL may cover the top surface and the side surface of the light emitting element layer EDL, and may protect the light emitting element layer EDL. The encapsulation layer TFEL may include at least one inorganic layer and at least one organic layer for encapsulating the light emitting element layer EDL.

The touch sensing unit TSU may be disposed on the encapsulation layer TFEL. The touch sensing unit TSU may include a plurality of touch electrodes for sensing a user's touch in a capacitive manner, and touch lines connecting the plurality of touch electrodes to the touch driver 400. For example, the touch sensing unit TSU may sense the user's touch by using a mutual capacitance method or a self-capacitance method. The plurality of touch electrodes of the touch sensing unit TSU may be disposed in a touch sensor area overlapping the display area DA. The touch lines of the touch sensing unit TSU may be disposed in a touch peripheral area overlapping the non-display area NDA.

For another example, the touch sensing unit TSU may be disposed on a separate substrate disposed on the display unit DU. In this case, the substrate SUB supporting the touch sensing unit TSU may be a base member that encapsulates the display unit DU.

The color filter layer CFL may be disposed on the touch sensing unit TSU. The color filter layer CFL may include a plurality of color filters respectively corresponding to the plurality of emission areas. Each of the color filters may selectively transmit light of a given wavelength and may block or absorb light of a different wavelength. The color filter layer CFL may absorb a part of light coming from the outside of the display device 10 to reduce reflected light due to external light. Accordingly, the color filter layer CFL may prevent color distortion caused by reflection of the external light.

Since the color filter layer CFL is directly disposed on the touch sensing unit TSU, the display device 10 may not require a separate substrate for the color filter layer CFL. Therefore, the thickness of the display device 10 may be relatively reduced.

The sub-region SBA of the display panel 100 may extend from one side or a side of the main region MA. The sub-region SBA may include a flexible material which can be bent, folded or rolled. For example, in case that the sub-region SBA is bent, the sub-region SBA may overlap the main region MA in a thickness direction (Z-axis direction). The sub-region SBA may include the display driver 200 and the pad unit electrically connected to the circuit board 300.

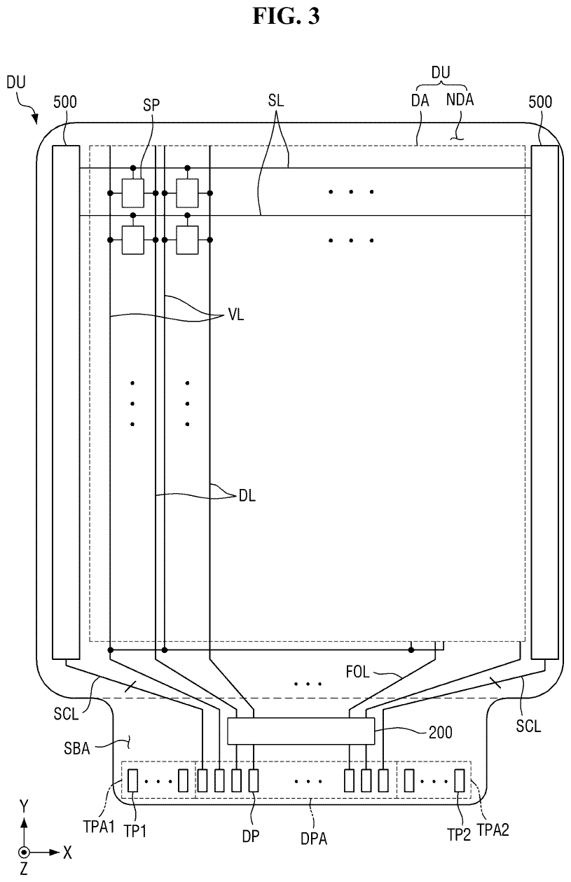

FIG. 3 is a schematic plan view illustrating a display unit of a display device according to an embodiment.

Referring to FIG. 3, the display unit DU may include the display area DA and the non-display area NDA.

The display area DA, which is an area for displaying an image, may be defined as the central area of the display panel 100. The display area DA may include a plurality of pixels SP, a plurality of scan lines SL, a plurality of data lines DL, and a plurality of power lines VL. Each of the plurality of pixels SP may be defined as the smallest unit that outputs light.

The plurality of scan lines SL may supply the scan signals received from a scan driver 500 to the plurality of pixels SP. The plurality of scan lines SL may extend in an X-axis direction and may be spaced apart from each other in a Y-axis direction that crosses (or intersects) the X-axis direction.

The plurality of data lines DL may supply the data voltages received from the display driver 200 to the plurality of pixels SP. The plurality of data lines DL may extend in the Y-axis direction and may be spaced apart from each other in the X-axis direction.

The plurality of power lines VL may supply the power voltage received from a display pad unit DP to the plurality of pixels SP. Here, the power voltage may be at least one of a driving voltage, a high-potential voltage, an initialization voltage, a reference voltage, a bias voltage, or a low-potential voltage. The plurality of power lines VL may extend in the Y-axis direction and may be spaced apart from each other in the X-axis direction.

The non-display area NDA may surround the display area DA. The non-display area NDA may include a scan driver 500, fan-out lines FOL, and scan control lines SCL. The scan driver 500 may generate a plurality of scan signals based on the scan control signal, and may sequentially supply the plurality of scan signals to the plurality of scan lines SL according to a set order.

The fan-out lines FOL may extend from the display driver 200 to the display area DA. The fan-out lines FOL may supply the data voltage received from the display driver 200 to the plurality of data lines DL.

The scan control line SCL may extend from the display pad unit DP to the scan driver 500. The scan control line SCL may supply the scan control signal received from the display pad unit DP to the scan driver 500.

The sub-region SBA may include the display driver 200, a display pad area DPA, and first and second touch pad areas TPA1 and TPA2.

The display driver 200 may output signals and voltages for driving the display panel 100 to the fan-out lines FOL. The display driver 200 may supply a data voltage to the data line DL through the fan-out lines FOL. The data voltage may be supplied to the plurality of pixels SP to determine the luminance of the plurality of pixels SP.

The display pad area DPA, the first touch pad area TPA1, and the second touch pad area TPA2 may be disposed at the edge of the sub-region SBA. The display pad area DPA, the first touch pad area TPA1, and the second touch pad area TPA2 may be electrically connected to the circuit board 300 by using a low-resistance and high-reliability material such as an anisotropic conductive film or a self assembly anisotropic conductive paste (SAP).

The display pad area DPA may include a plurality of display pad units DP. The plurality of display pad units DP may be electrically connected to a graphic system through the circuit board 300. The plurality of display pad units DP may be connected to the circuit board 300 to receive digital video data, and may supply the digital video data to the display driver 200. The plurality of display pad units DP may supply scan control signals to a scan driver 500 through the scan control line SCL.

The first touch pad area TPA1 may be disposed on one side or a side of the display pad area DPA, and may include a plurality of first touch pad units TP1. The plurality of first touch pad units TP1 may be electrically connected to the touch driver 400 disposed on the circuit board 300. The plurality of first touch pad units TP1 may supply a touch driving signal to the plurality of driving electrodes through a plurality of driving lines.

The second touch pad area TPA2 may be disposed on the other side of the display pad area DPA, and may include a plurality of second touch pad units TP2. The plurality of second touch pad units TP2 may be electrically connected to the touch driver 400 disposed on the circuit board 300. The touch driver 400 may receive a touch sensing signal through a plurality of sensing lines connected to the plurality of second touch pad units TP2, and may sense a change in mutual capacitance between the driving electrode and a sensing electrode.

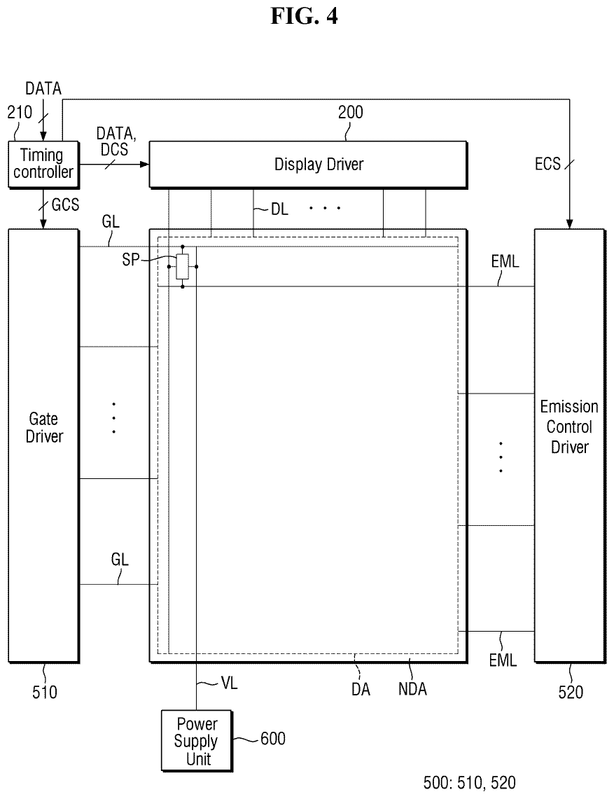

FIG. 4 is a block diagram illustrating a display panel and a display driver according to an embodiment.

Referring to FIG. 4, the display panel 100 may include the display area DA and the non-display area NDA.

The display area DA may include a plurality of pixels SP, a plurality of power lines VL, a plurality of gate lines GL, a plurality of emission control lines EML, and a plurality of data lines DL connected to the plurality of pixels SP.

Each of the pixels SP may be connected to the gate line GL, the data line DL, the emission control line EML, and the power line VL. Each of the pixels SP may include a plurality of transistors, a light emitting element, and a capacitor.

The gate lines GL may extend in the X-axis direction and may be spaced apart from each other in the Y-axis direction that crosses (or intersects) the X-axis direction. The gate lines GL may sequentially supply gate signals to the plurality of pixels SP.

The emission control lines EML may extend in the X-axis direction and may be spaced apart from each other in the Y-axis direction. The emission control lines EML may sequentially supply emission signals to the plurality of pixels SP.

The data lines DL may extend in the Y-axis direction and may be spaced apart from each other in the X-axis direction. The data lines DL may supply the data voltage to the plurality of pixels SP. The data voltage may determine the luminance of each of the plurality of pixels SP.

The power lines VL may extend in the Y-axis direction and may be spaced apart from each other in the X-axis direction. The power lines VL may supply a power voltage to the plurality of pixels SP. The power voltage may be any one of a driving voltage, a high-potential voltage, an initialization voltage, a reference voltage, a bias voltage, and a low-potential voltage.

A timing controller 210 may receive digital video data DATA and timing signals from the circuit board 300. The timing controller 210 may generate a data control signal DCS based on the timing signals. The timing controller 210 may control the operation timing of the display driver 200 by supplying the digital video data DATA and the data control signal DCS to the display driver 200. The display driver 200 may convert the digital video data DATA into analog data voltages and output them to the data lines DL. The timing controller 210 may generate a gate control signal GCS based on the timing signals. The timing controller 210 may supply the gate control signal GCS to a gate driver 510 to control the operation timing of the gate driver 510. The timing controller 210 may generate an emission control signal ECS based on the timing signals. The timing controller 210 may supply the emission control signal ECS to an emission control driver 520 to control the operation timing of the emission control driver 520.

The gate driver 510 and the emission control driver 520 may be disposed on the left or right side of the non-display area NDA. For example, the gate driver 510 and the emission control driver 520 may be disposed on the left and right sides of the non-display area NDA, but are not limited thereto. For another example, the gate driver 510 may be disposed on the left side of the non-display area NDA, and the emission control driver 520 may be disposed on the right side of the non-display area NDA.

The gate driver 510 may include a plurality of transistors and generate gate signals based on the gate control signal GCS. Gate signals of the gate driver 510 may select pixels SP to which the data voltage is supplied, and the selected pixels SP may receive the data voltage through the data lines DL. The emission control driver 520 may include a plurality of transistors and generate emission signals based on the emission control signal ECS. For example, the transistors of the gate driver 510 and the transistors of the emission control driver 520 may be formed in the same layer as the transistors of each pixel SP. The gate driver 510 may supply gate signals to the gate lines GL, and the emission control driver 520 may supply emission signals to the emission control lines EML.

A power supply unit 600 may apply supply voltages to the display driver 200 and the display panel 100. The power supply unit 600 may generate a driving voltage to supply it to a driving voltage line, may generate an initialization voltage to supply it to an initialization voltage line, may generate a bias voltage to supply it to a bias voltage line, and may generate a low potential-voltage to supply it to a low-potential voltage line.

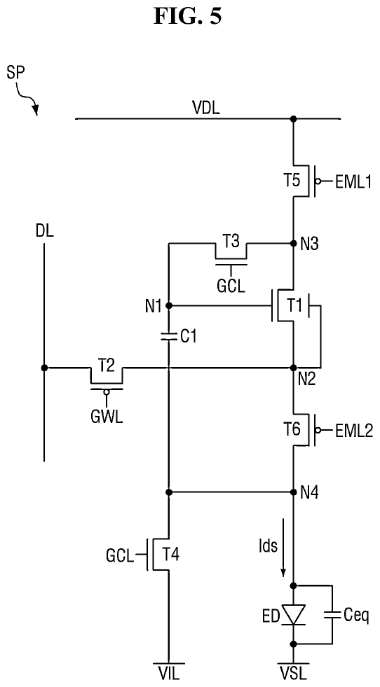

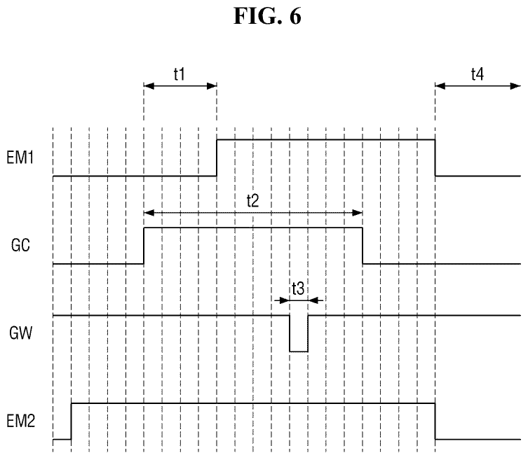

FIG. 5 is a schematic diagram of an equivalent circuit of a pixel of a display device according to an embodiment, and FIG. 6 is a waveform diagram of signals supplied to the pixel shown in FIG. 5.

Referring to FIGS. 5 and 6, the pixel SP may be connected to a first gate line GWL, a second gate line GCL, a first emission control line EML1, a second emission control line EML2, a data line DL, a driving voltage line VDL, an initialization voltage line VIL, and a low-potential line VSL.

The pixel SP may include a light emitting element ED and a pixel circuit that drives the light emitting element ED. The pixel circuit may include first to sixth transistors T1 to T6, and a capacitor C1.

The first transistor T1 may control a driving current supplied to the light emitting element ED. The first transistor T1 may include a gate electrode, a drain electrode and a source electrode. The gate electrode of the first transistor T1 may be connected to a first node N1, the drain electrode thereof may be connected to a third node N3, and the source electrode thereof may be connected to a second node N2. The first transistor T1 may control the drain-source current Ids (hereinafter, referred to as “driving current”) according to the data voltage applied to the gate electrode. The driving current Ids flowing through the channel of the first transistor T1 may be proportional to the square of the difference between the threshold voltage Vth and the voltage Vgs between the gate electrode and the source electrode of the first transistor T1 (Ids=k′×(Vgs−Vth)²), where k denotes a proportional coefficient determined by the structure and physical properties of the first transistor T1, Vgs denotes the drain-source voltage of the first transistor T1, and Vth denotes the threshold voltage of the first transistor T1.

The first transistor T1 may include a bias electrode. The bias electrode of the first transistor T1 may be electrically connected to a source electrode of the first transistor T1 through a second node N2 and may overlap a semiconductor region of the first transistor T1. The bias electrode of the first transistor T1 can stably control the driving current Ids by stabilizing an operating point of the first transistor T1.

The light emitting element ED may receive the driving current Ids and emit light. The amount of light emitted from the light emitting element ED or the luminance of the light emitting element ED may be proportional to the magnitude of the driving current Ids. The light emitting element ED may include a first electrode, a second electrode, and a light emitting layer disposed between the first electrode and the second electrode. The first electrode of the light emitting element ED may be connected to a fourth node N4. The first electrode of the light emitting element ED may be connected to the drain electrode of the fourth transistor T4 and the drain electrode of the sixth transistor T6 through the fourth node N4. The second electrode of the light emitting element ED may be connected to the low-potential line VSL to receive a low-potential voltage therefrom. For example, the first electrode of the light emitting clement ED may be an anode electrode or a pixel electrode, while the second electrode thereof may be a cathode electrode or a common electrode. It is, however, to be understood that the disclosure is not limited thereto. Parasitic capacitance Ceq may be formed between the first and second electrodes of the light emitting clement ED.

The second transistor T2 may be turned on by a first gate signal GW of the first gate line GWL to electrically connect the data line DL and a second node N2 which is the source electrode of the first transistor T1. The second transistor T2 turned on based on the first gate signal GW may supply a data voltage to the second node N2. The second transistor T2 may have a gate electrode connected to the first gate line GWL, a source electrode connected to the data line DL, and a drain electrode connected to the second node N2.

The third transistor T3 may be turned on by a second gate signal GC of the second gate line GCL to electrically connect a first node NI which is the gate electrode of the first transistor T1 and a third node N3 which is the drain electrode of the first transistor T1. The third transistor T3 may have a gate electrode connected to the second gate line GCL, a drain electrode connected to the third node N3, and a source electrode connected to the first node N1.

The fourth transistor T4 may be turned on by the second gate signal GC of the second gate line GCL to electrically connect the initialization voltage line VIL and a fourth node N4 which is the first electrode of the light emitting element ED. The fourth transistor T4 turned on based on the second gate signal GC may supply an initialization voltage to the first electrode of the light emitting element ED. The fourth transistor T4 may have a gate electrode connected to the second gate line GCL, a drain electrode connected to the fourth node N4, and a source electrode connected to the initialization voltage line VIL.

The fifth transistor T5 may be turned on by a first emission signal EM1 of the first emission control line EML1 to electrically connect the driving voltage line VDL and the third node N3 which is the drain electrode of the first transistor T1. The fifth transistor T5 may have a gate electrode connected to the first emission control line EML1, a source electrode connected to the driving voltage line VDL, and a drain electrode connected to the third node N3.

The sixth transistor T6 may be turned on by a second emission signal EM2 of the second emission control line EML2 to electrically connect the second node N2 which is the source electrode of the first transistor T1 and the fourth node N4 which is the first electrode of the light emitting element ED. The sixth transistor T6 may have a gate electrode connected to the second emission control line EML2, a source electrode connected to the second node N2, and the drain electrode connected to the fourth node N4.

In case that the fifth transistor T5, the first transistor T1, and the sixth transistor T6 are all turned on, a driving current Ids may be supplied to the light emitting element ED.

The first transistor T1, the third transistor T3, and the fourth transistor T4 may include an oxide-based semiconductor region. For example, each of the first transistor T1, the third transistor T3, and the fourth transistor T4 may have a coplanar structure in which a gate electrode is disposed above an oxide-based semiconductor region. A transistor having such a coplanar structure has excellent leakage current characteristics and allows for low-frequency driving, thereby reducing power consumption. Accordingly, the display device 10 may include the first transistor T1, the third transistor T3, and the fourth transistor T4 having good leakage current characteristics, so that it is possible to prevent leakage current from flowing inside the pixels, and to maintain the voltage inside the pixels stably.

The first transistor T1, the third transistor T3, and the fourth transistor T4 may be n-type transistors. Each of the first transistor T1, the third transistor T3, and the fourth transistor T4 may include a drain electrode and a source electrode doped into n-type. For example, each of the first transistor T1, the third transistor T3, and the fourth transistor T4 may output a current flowing into the drain electrode to the source electrode in response to a gate-high voltage applied to the gate electrode.

The second transistor T2, the fifth transistor T5, and the sixth transistor T6 may include a silicon-based semiconductor region. For example, the second transistor T2, the fifth transistor T5, and the sixth transistor T6 may include a semiconductor region made of low temperature polycrystalline silicon (LTPS). A semiconductor region made of low temperature polycrystalline silicon may have high electron mobility and excellent turn-on characteristics. Therefore, the display device 10 including the second transistor T2, the fifth transistor T5, and the sixth transistor T6 with excellent turn-on characteristics can stably and efficiently drive the pixels SP.

The second transistor T2, the fifth transistor T5, and the sixth transistor T6 may correspond to a p-type transistor. Each of the second transistor T2, the fifth transistor T5, and the sixth transistor T6 may include a source electrode and a drain electrode doped into p-type. For example, each of the second transistor T2, the fifth transistor T5, and the sixth transistor T6 may output a current flowing into the source electrode to the drain electrode in response to a gate-low voltage applied to the gate electrode.

The capacitor C1 may be connected to the first node N1 which is the gate electrode of the first transistor T1 and the fourth node N4 which is the first electrode of the light emitting element ED. For example, as a first capacitor electrode of the capacitor C1 is connected to the first node N1 and a second capacitor electrode of the capacitor C1 is connected to the fourth node N4, the potential difference between the gate electrode of the first transistor T1 and the first electrode of the light emitting element ED may be maintained.

Referring to FIG. 6 as well as FIG. 5, the display device 10 may be driven through first to fourth periods t1 to t4 of one frame. The pixel SP may receive a first gate signal GW, a second gate signal GC, a first emission signal EM1, and a second emission signal EM2.

The fifth transistor T5 may receive a low level first emission signal EM1 during the first period t1, and the third transistor T3 may receive a high level second gate signal GC during the second period t2. The first half of the second period t2 may include the first period t1. For example, the starting point of the first and second periods t1 and t2 may be the same and the end point of the second period t2 may be after the end point of the first period t1, but the disclosure is not limited thereto. Accordingly, as the driving voltage is supplied to the first node N1 which is the gate electrode of the first transistor T1, the voltage of the first node N1 may be initialized during the first period t1.

The fourth transistor T4 may receive the high level second gate signal GC during the second period t2. Accordingly, as the initialization voltage is supplied to the fourth node N4 which is the first electrode of the light emitting element ED, the fourth node N4 may be discharged to the initialization voltage during the second period t2.

The second transistor T2 may receive a low level first gate signal GW during the third period t3. Accordingly, the second transistor T2 may supply the data voltage during the third period t3 to the second node N2 which is the source electrode of the first transistor T1. The second period t2 may include a third period t3. For example, the starting point of the third period t3 may be after the end point of the first period t1 and before the end point of the second period t2, but is not limited thereto. In the case where the source electrode of the first transistor T1 receives the data voltage, the first transistor may be turned on because the gate-source voltage Vgs of the first transistor T1 is greater than the threshold voltage Vth. The first transistor T1 may be turned on until the gate-source voltage Vgs reaches the threshold voltage Vth of the first transistor T1. Accordingly, the data voltage and the threshold voltage Vth may be sampled at the gate electrode of the first transistor T1.

The fifth transistor T5 may receive a low level first emission signal EMI during the fourth period t4 after the second and third periods t2 and t3, and the sixth transistor T6 may receive a low level second emission signal EM2 during the fourth period t4. Accordingly, the fifth and sixth transistors T5 and T6 may be turned on, and the driving current Ids may be supplied to the light emitting element ED.

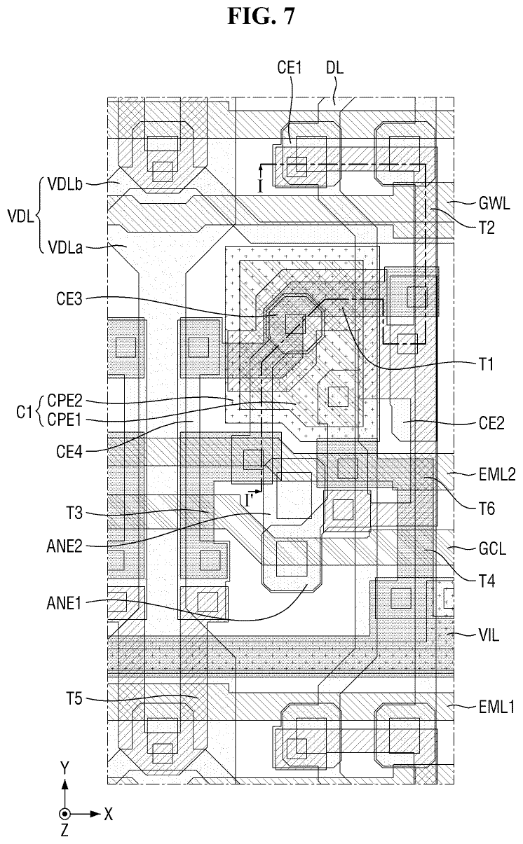

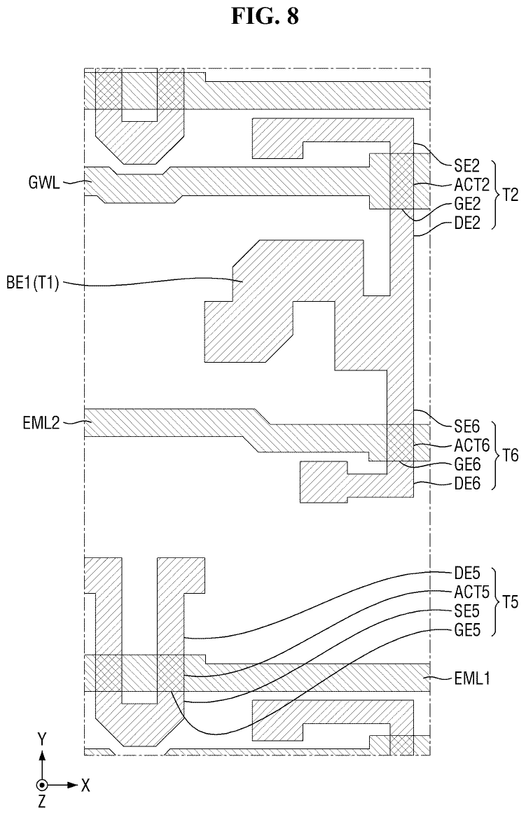

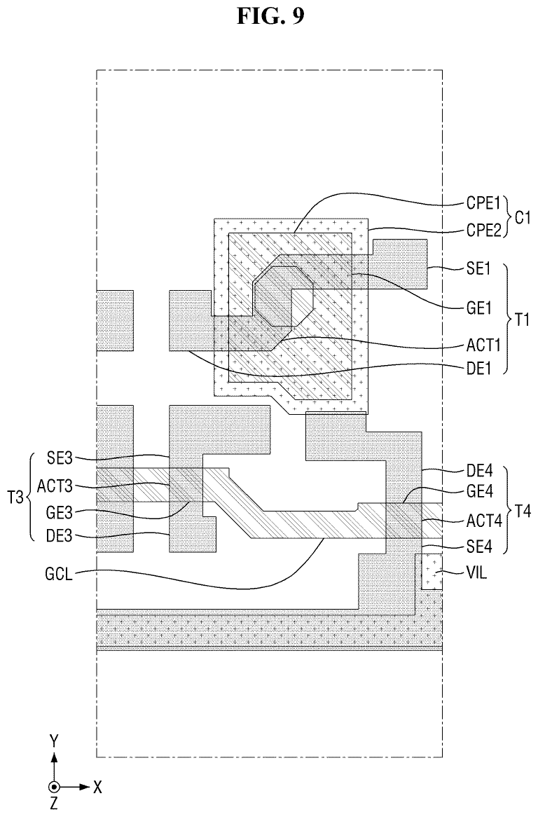

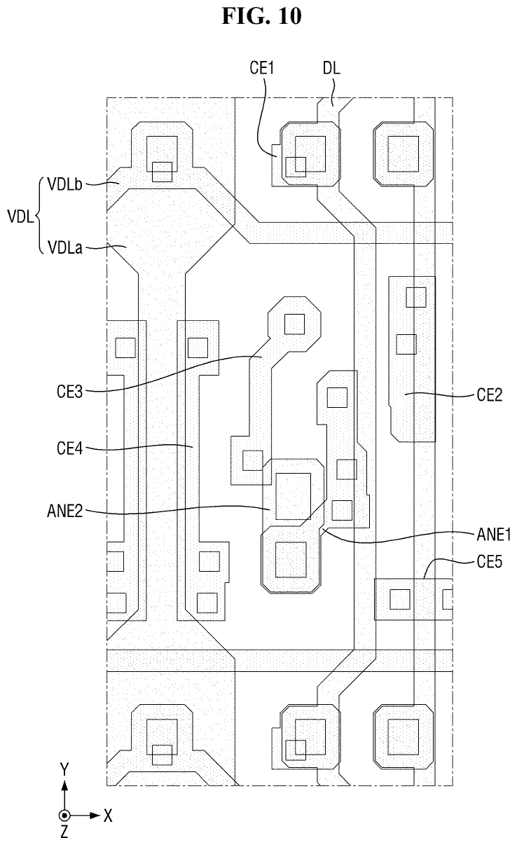

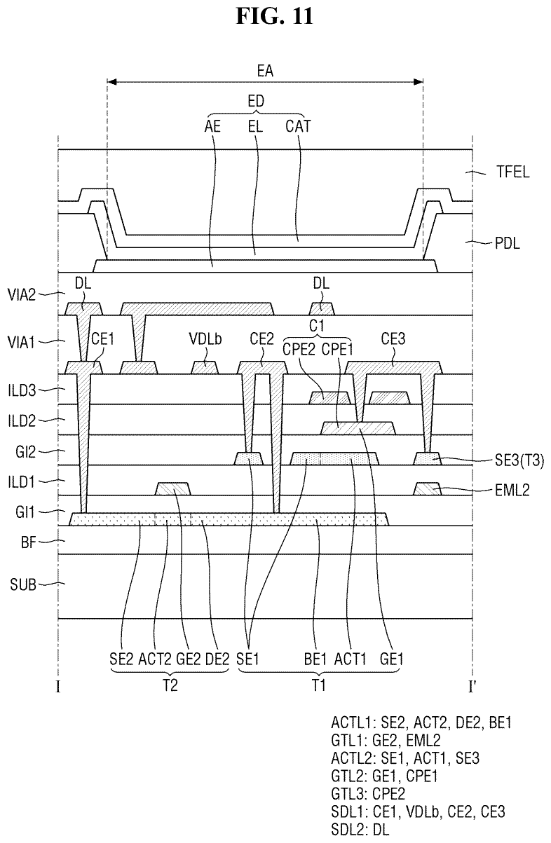

FIG. 7 is a plan diagram illustrating a pixel shown in FIG. 5. FIG. 8 is a diagram illustrating some layers of the plan diagram of FIG. 7 and illustrates a stacked structure of a first active layer ACTL1 and a first gate layer GTL1. FIG. 9 is a diagram illustrating some other layers of the plan diagram of FIG. 7 and illustrates a stacked structure of a second active layer ACTL2, a second gate layer GTL2, and a third gate layer GTL3. FIG. 10 is a diagram illustrating yet some other layers of the plan diagram of FIG. 7 and illustrates a stacked structure of a first source metal layer SDL1 and a second source metal layer SDL2. FIG. 11 is a schematic cross-sectional view taken along line I-I′ of FIG. 7.

Referring to FIGS. 7 to 11, the pixel SP may be connected to the first gate line GWL, the second gate line GCL, the first emission control line EML1, the second emission control line EML2, the data line DL, the driving voltage line VDL, the initialization voltage line VIL, and the low-potential line VSL.

The first transistor T1 may include a semiconductor region ACT1, a gate electrode GE1, a drain electrode DE1, a source electrode SE1, and a bias electrode BE1. The bias electrode BE1 of the first transistor T1 may be disposed in the first active layer ACTL1. The semiconductor region ACT1, the drain electrode DE1, and the source electrode SE1 of the first transistor T1 may be disposed in the second active layer ACTL2. The gate electrode GE1 of the first transistor T1 may be disposed in the second gate layer GTL2. The gate electrode GE1 of the first transistor T1 may be a portion of a first capacitor electrode CPE1 of the second gate layer GTL2 and overlap the semiconductor region ACT1 and the bias electrode BE1 of the first transistor T1. For example, the bias electrode BE1 of the first transistor T1 may be formed by converting the low temperature polycrystalline silicon (LTPS) into a conductor, and the semiconductor region ACT1 of the first transistor T1 may include oxide. Accordingly, the bias electrode BE1 of the first transistor T1 may be formed by being doped into a p-type, and the drain electrode DE1 and the source electrode SE1 of the first transistor T1 may be formed by being doped into n-type. Since the first transistor T1 may include the bias electrode BE1 disposed in the first active layer ACTL1, the display device 10 may reduce the number of contact holes in the pixel circuit and readily design high-resolution pixels.

The gate electrode GE1 of the first transistor T1 may be electrically connected to a source electrode SE3 of the third transistor T3 through a third connection electrode CE3 of the first source metal layer SDL1. The drain electrode DE1 of the first transistor T1 may be electrically connected to a drain electrode DE3 of the third transistor T3 and a drain electrode DE5 of the fifth transistor T5 through a fourth connection electrode CE4 of the first source metal layer SDL1. The source electrode SE1 of the first transistor T1 may be electrically connected to the bias electrode BE1 of the first transistor T1, a drain electrode DE2 of the second transistor T2, and a source electrode SE6 of the sixth transistor T6 through a second connection electrode CE2 of the first source metal layer SDL1.

The second transistor T2 may include a semiconductor region ACT2, a gate electrode GE2, a source electrode SE2, and the drain electrode DE2. The semiconductor region ACT2, the source electrode SE2, and the drain electrode DE2 of the second transistor T2 may be disposed in the first active layer ACTL1 and the gate electrode GE2 of the second transistor T2 may be disposed in the first gate layer GTL1. The gate electrode GE2 of the second transistor T2 may be a portion of the first gate line GWL of the first gate layer GTL1 and overlap the semiconductor region ACT2 of the second transistor T2. For example, the semiconductor region ACT2 of the second transistor T2 may include low temperature polycrystalline silicon (LTPS).

The source electrode SE2 of the second transistor T2 may be electrically connected to the data line of the second source metal layer SDL2 through a first connection electrode CE1 of the first source metal layer SDL1. The drain electrode DE2 of the second transistor T2 may be connected to the bias electrode BE1 of the first transistor T1 and the source electrode SE6 of the sixth transistor T6. The drain electrode DE2 of the second transistor T2 may be electrically connected to the source electrode SE1 of the first transistor T1 through the second connection electrode CE2.

The third transistor T3 may include a semiconductor region ACT3, a gate electrode GE3, a drain electrode DE3, and a source electrode SE3. The semiconductor region ACT3, the drain electrode DE3, and the source electrode SE3 of the third transistor T3 may be disposed in the second active layer ACTL2 and the gate electrode GE3 of the third transistor T3 may be disposed in the second gate layer GTL2. The gate electrode GE3 of the third transistor T3 may be a portion of the second gate line GCL of the second gate layer GTL2 and overlap the semiconductor region ACT3 of the third transistor T3. For example, the semiconductor region ACT3 of the third transistor T3 may include an oxide.

The drain electrode DE3 of the third transistor T3 may be electrically connected to the drain electrode DE1 of the first transistor T1 and the drain electrode DE5 of the fifth transistor T5 through the fourth connection electrode CE4. The source electrode SE3 of the third transistor T3 may be electrically connected to the gate electrode GE1 of the first transistor T1 through the third connection electrode CE3.

The fourth transistor T4 may include a semiconductor region ACT4, a gate electrode GE4, a drain electrode DE4, and a source electrode SE4. The semiconductor region ACT4, the drain electrode DE4, and the source electrode SE4 of the fourth transistor T4 may be disposed in the second active layer ACTL2 and the gate electrode GE4 of the fourth transistor T4 may be disposed in the second gate layer GTL2. The gate electrode GE4 of the fourth transistor T4 may be a portion of the second gate line GCL of the second gate layer GTL2 and overlap the semiconductor region ACT4 of the fourth transistor T4. For example, the semiconductor region ACT4 of the fourth transistor T4 may include an oxide.

The drain electrode DE4 of the fourth transistor T4 may be electrically connected to a drain electrode DE6 of the sixth transistor T6 and the first electrode of the light emitting element ED through a first anode connection electrode ANE1 of the first source metal layer SDL1. The source electrode SE4 of the fourth transistor T4 may be electrically connected to the initialization voltage line VIL of the third gate layer GTL3 through a fifth connection electrode CE5 of the first source metal layer SDL1.

The fifth transistor T5 may include a semiconductor region ACT5, a gate electrode GE5, a source electrode SE5, and the drain electrode DE5. The semiconductor region ACT5, the source electrode SE5, and the drain electrode DE5 of the fifth transistor T5 may be disposed in the first active layer ACTL1 and the gate electrode GE5 of the fifth transistor T5 may be disposed in the first gate layer GTL1. The gate electrode GES of the fifth transistor T5 may be a portion of the first emission control line EML1 of the first gate layer GTL1 and overlap the semiconductor region ACT5 of the fifth transistor T5. For example, the semiconductor region ACT5 of the fifth transistor T5 may include a low temperature polycrystalline silicon (LTPS).

The source electrode SE5 of the fifth transistor T5 may be electrically connected to a first portion VDLa and a second portion VDLb of the driving voltage line VDL. The first portion VDLa of the driving voltage line VDL may be disposed in the second source metal layer SDL2 to extend in the Y-axis direction, and the second portion VDLb of the driving voltage line VDL may be disposed in the first source metal layer SDL1 to extend in the X-axis direction. The drain electrode DE5 of the fifth transistor T5 may be electrically connected to the drain electrode DE1 of the first transistor T1 and the drain electrode DE3 of the third transistor T3 through the fourth connection electrode CE4.

The sixth transistor T6 may include a semiconductor region ACT6, a gate electrode GE6, the source electrode SE6, and the drain electrode DE6. The semiconductor region ACT6, the source electrode SE6, and the drain electrode DE6 of the sixth transistor T6 may be disposed in the first active layer ACTL1 and the gate electrode GE6 of the sixth transistor T6 may be disposed in the first gate layer GTL1. The gate electrode GE6 of the sixth transistor T6 may be a portion of the second emission control line EML2 and overlap the semiconductor region ACT6 of the sixth transistor T6. For example, the semiconductor region ACT6 of the sixth transistor T6 may include a low temperature polycrystalline silicon (LTPS).

The source electrode SE6 of the sixth transistor T6 may be connected to the bias electrode BE1 of the first transistor T1 and the drain electrode DE2 of the second transistor T2. The source electrode SE6 of the sixth transistor T6 may be electrically connected to the source electrode SE1 of the first transistor T1 through the second connection electrode CE2. The drain electrode DE6 of the sixth transistor T6 may be electrically connected to the drain electrode DE4 of the fourth transistor T4 and the first electrode of the light emitting element ED through the first anode connection electrode ANE1.

The capacitor C1 may include the first capacitor electrode CPE1 and a second capacitor electrode CPE2. The first and second capacitor electrodes CPE1 and CPE2 may overlap each other. The first capacitor electrode CPE1 of the capacitor C1 may be disposed in the second gate layer GTL2, and the second capacitor electrode CPE2 thereof may be disposed in the third gate layer GTL3. The first capacitor electrode CPE1 may include the gate electrode GE1 of the first transistor T1. The second capacitor electrode CPE2 may be electrically connected to the drain electrode DE4 of the fourth transistor T4, the drain electrode DE6 of the sixth transistor T6, and the first electrode of the light emitting element ED through the first anode connection electrode ANE1.

In FIG. 11, the display panel 100 may include a substrate SUB, a transistor layer TFTL, a light emitting element layer EDL, and an encapsulation layer TFEL.

The substrate SUB may be a base substrate or a base member. The substrate SUB may be a flexible substrate which can be bent, folded or rolled. For example, the substrate SUB may include a polymer resin such as polyimide (PI), but is not limited thereto. For another example, the substrate SUB may include a glass material or a metal material.

The transistor layer TFTL may include a buffer layer BF, a first active layer ACTL1, a first gate insulating layer GI1, a first gate layer GTL1, a first interlayer insulating layer ILD1, a second active layer ACTL2, a second gate insulating layer GI2, a second gate layer GTL2, a second interlayer insulating layer ILD2, a third gate layer GTL3, a third interlayer insulating layer ILD3, a first source metal layer SDL1, a first via layer VIA1, a second source metal layer SDL2, and a second via layer VIA2.

The buffer layer BF may be disposed on the substrate SUB. For example, the buffer layer BF may include an inorganic layer capable of preventing permeation of air or moisture. For example, the buffer layer BF may include a plurality of inorganic layers laminated alternately each other.

The first active layer ACTL1 may be disposed on the buffer layer BF. The first active layer ACTL1 may include a silicon-based material. For example, the first active layer ACTL1 may be made of low temperature polycrystalline silicon LTPS. The first active layer ACTL1 may include the semiconductor regions ACT2, ACT5, and ACT6, the source electrodes SE2, SE5, and SE6, and the drain electrodes DE2, DE5, and DE6 of the respective second transistor T2, the fifth transistor T5, and the sixth transistor T6.

The first gate insulating layer GI1 may be disposed on the first active layer ACTL1. The first gate insulating layer GI1 may insulate the first active layer ACTL1 from the first gate layer GTL1.

The first gate layer GTL1 may be disposed on the first gate insulating layer GI1. The first gate layer GTL1 may include the gate electrodes GE2, GE5, and GE6 of the respective second transistor T2, the fifth transistor T5, and the sixth transistor T6; the first gate line GWL; and the first and second emission control lines EML1 and EML2.

The first interlayer insulating layer ILD1 may be disposed on the first gate layer GTL1. The first interlayer insulating layer ILDI may insulate the first gate layer GTL1 from the second active layer ACTL2.

The second active layer ACTL2 may be disposed on the first interlayer insulating layer ILD1. The second active layer ACTL2 may include an oxide-based material. The second active layer ACTL2 may include the semiconductor regions ACT1, ACT3, and ACT4, the drain electrodes DE1, DE3, and DE4, and the source electrodes SE1, SE3, and SE4 of the respective first transistor T1, the third transistor T3, and the fourth transistor T4.

The second gate insulating layer GI2 may be disposed on the second active layer ACTL2. The second gate insulating layer GI2 may insulate the second active layer ACTL2 from the second gate layer GTL2.

The second gate layer GTL2 may be disposed on the second gate insulating layer GI2. The second gate layer GTL2 may include the gate electrodes GE1, GE3, and GE4 of the respective first transistor T1, the third transistor T3, and the fourth transistor T4; the second gate line GCL; and the first capacitor electrode CPE1.

The second interlayer insulating layer ILD2 may be disposed on the second gate layer GTL2. The second interlayer insulating layer ILD2 may insulate the second gate layer GTL2 from the third gate layer GTL3.

The third gate layer GTL3 may be disposed on the second interlayer insulating layer ILD2. The third gate layer GTL3 may include the second capacitor electrode CPE2 and the initialization voltage line VIL.

The third interlayer insulating layer ILD3 may be disposed on third gate layer GTL3. The third interlayer insulating layer ILD3 may insulate the third gate layer GTL3 from the first source metal layer SDL1.

The first source metal layer SDL1 may be disposed on the third interlayer insulating layer ILD3. The first source metal layer SDL1 may include the first to fifth connection electrodes CE1, CE2, CE3, CE4, and CE5, the first anode connection electrode ANE1, and the second portion VDLb of the driving voltage line VDL.

The first via layer VIA1 may be disposed on the first source metal layer SDL1. The first via layer VIA1 may insulate the first source metal layer SDL1 from the second source metal layer SDL2.

The second source metal layer SDL2 may be disposed on the first via layer VIA1. The second source metal layer SDL2 may include the data line DL, a second anode connection electrode ANE2, and the first portion VDLa of the driving voltage line VDL.

The second via layer VIA2 may be disposed on the second source metal layer SDL2. The second via layer VIA2 may insulate the second source metal layer SDL2 from a first electrode AE of the light emitting element ED.

The light emitting element layer EDL may include a pixel defining layer PDL and a light emitting element ED. The light emitting element ED may include the first electrode AE, a light emitting layer EL, and a second electrode CAT.

The pixel defining layer PDL may be disposed on a second via layer VIA2. The pixel defining layer PDL may define a plurality of emission areas EA. The pixel defining layer PDL may include an organic insulating material such as polyimide (PI).

The first electrode AE may be disposed on the second via layer VIA2. The first electrode AE may overlap one among the plurality of emission areas EA defined by the pixel defining layer PDL. The first electrode AE may receive a diving current from the pixel circuit of a pixel SP.

The light emitting layer EL may be disposed on the first electrode AE. For example, the light emitting layer EL may be an organic light emitting layer formed of an organic material, but the disclosure is not limited thereto. In case where the light emitting layer EL corresponds to an organic light emitting layer, the pixel circuit of the pixel SP applies a selectable voltage to the first electrode AE, and in case where the second electrode CAT receives a common voltage or a cathode voltage, holes may move to the organic light emitting layer EL through the hole transporting layer, and electrons may move to the organic light emitting layer EL through the electron transporting layer, and the holes and the electrons may be combined with each other in the organic light emitting layer to emit light.

The second electrode CAT may be disposed on the light emitting layer EL. For example, the second electrode CAT may be implemented as an electrode form that is not divided for each of the plurality of pixels SP and is common in the entire pixels SP. The second electrode CAT may be disposed on the light emitting layer EL in the plurality of emission areas, and may be disposed on the pixel defining layer PDL in the area excluding the plurality of emission areas.

The encapsulation layer TFEL may be disposed on the second electrode CAT to cover the plurality of light emitting elements ED. The encapsulation layer TFEL may include at least one inorganic layer to prevent oxygen or moisture from permeating into the plurality of light emitting elements ED. The encapsulation layer TFEL may include at least one organic layer to protect the plurality of light emitting elements ED from foreign substances such as dust.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A display device comprising:
a light emitting element disposed on a substrate;
a first transistor controlling a driving current supplied to the light emitting element;
a second transistor supplying a data voltage to a source electrode of the first transistor; and
a third transistor electrically connecting a drain electrode of the first transistor to a gate electrode of the first transistor, wherein
the second transistor comprises a semiconductor region disposed in a first active layer on the substrate and a gate electrode disposed in a first gate layer on the first active layer, and
the first transistor comprises a semiconductor region disposed in a second active layer on the first gate layer, a gate electrode disposed in a second gate layer on the second active layer, and a bias electrode disposed in the first active layer.

2. The display device of claim 1, wherein the bias electrode of the first transistor is electrically connected to the source electrode of the first transistor and overlaps the semiconductor region and the gate electrode of the first transistor.

3. The display device of claim 1, wherein
the first active layer comprises a silicon-based semiconductor region, and
the second active layer comprises an oxide-based semiconductor region.

4. The display device of claim 1, further comprising:
a capacitor electrically connected between the gate electrode of the first transistor and a first electrode of the light emitting element; and
a fourth transistor electrically connecting an initialization voltage line supplying an initialization voltage and the first electrode of the light emitting element.

5. The display device of claim 4, further comprising:
a fifth transistor electrically connecting a diving voltage line supplying a driving voltage to the drain electrode of the first transistor; and
a sixth transistor electrically connecting the source electrode of the first transistor to the first electrode of the light emitting element.

6. The display device of claim 5, wherein the bias electrode of the first transistor is electrically connected to a source electrode of the sixth transistor.

7. A display device comprising:
a light emitting element disposed on a substrate;
a first transistor controlling a driving current supplied to the light emitting element;
a second transistor supplying a data voltage to a source electrode of the first transistor;
a third transistor electrically connecting a drain electrode of the first transistor to a gate electrode of the first transistor; and
a capacitor electrically connected between the gate electrode of the first transistor and a first electrode of the light emitting element,
wherein the first transistor comprises a semiconductor region including an oxide, a drain electrode and a source electrode doped into n-type, and a bias electrode doped into p-type.

8. The display device of claim 7, wherein the bias electrode of the first transistor and a semiconductor region of the second transistor are disposed on a same layer.

9. The display device of claim 7, wherein
the second transistor comprises a source electrode and a drain electrode doped into p-type, and
the third transistor comprises a drain electrode and a source electrode doped into n-type.

10. The display device of claim 7, wherein the bias electrode of the first transistor is electrically connected to the source electrode of the first transistor and overlaps the semiconductor region and the gate electrode of the first transistor.

11. The display device of claim 7, further comprising:
a fourth transistor electrically connecting an initialization voltage line supplying an initialization voltage to a first electrode of the light emitting element.

12. The display device of claim 11, further comprising:
a fifth transistor electrically connecting a driving voltage line supplying a driving voltage to the drain electrode of the first transistor; and
a sixth transistor electrically connecting the source electrode of the first transistor to the first electrode of the light emitting element.

13. The display device of claim 12, wherein
the fourth transistor comprises a drain electrode and a source electrode doped into n-type, and
each of fifth transistor and the sixth transistor comprises a source electrode and a drain electrode doped into p-type.

14. A display device comprising:
a first active layer disposed on a substrate, the first active layer comprising a silicon-based semiconductor region;
a first gate layer disposed on the first active layer;
a second active layer disposed on the first gate layer, the second active layer comprising an oxide-based semiconductor region;
a second gate layer disposed on the second active layer;
a first transistor comprising a semiconductor region disposed in the second active layer, a gate electrode disposed in the second gate layer, and a bias electrode disposed in the first active layer;
a second transistor comprising a semiconductor region disposed in the first active layer and supplying a data voltage to a source electrode of the first transistor; and
a third transistor comprising a semiconductor region disposed in the second active layer and electrically connecting a drain electrode of the first transistor to the gate electrode of the first transistor.

15. The display device of claim 14, further comprising:
a third gate layer disposed on the second gate layer; and
a capacitor comprising a first capacitor electrode disposed in the second gate layer to comprise the gate electrode of the first transistor and a second capacitor electrode disposed in the third gate layer.

16. The display device of claim 15, further comprising:
a first source metal layer disposed on the third gate layer;
a second source metal layer disposed on the first source metal layer;
a first connection electrode disposed in the first source metal layer electrically connected to a source electrode of the second transistor; and
a data line disposed in the second source metal layer to supply a data voltage to the first connection electrode.

17. The display device of claim 16, further comprising:
a second connection electrode disposed in the first source metal layer to electrically connect the source electrode of the first transistor, the bias electrode of the first transistor, and a drain electrode of the second transistor.

18. The display device of claim 16, further comprising:
a third connection electrode disposed in the first source metal layer to electrically connect the gate electrode of the first transistor to a source electrode of the third transistor.

19. The display device of claim 16, further comprising:
a light emitting element disposed on the second source metal layer;
a driving voltage line disposed in the first source metal layer and supplying a driving voltage;
an initialization voltage line disposed in the third gate layer and supplying an initialization voltage;
a fourth transistor comprising a semiconductor region disposed in the second active layer and electrically connecting the initialization voltage line to a first electrode of the light emitting element;
a fifth transistor comprising a semiconductor region disposed in the first active layer and electrically connecting the driving voltage line to the drain electrode of the first transistor; and
a sixth transistor comprising a semiconductor region disposed in the first active layer and electrically connecting the source electrode of the first transistor to the first electrode of the light emitting element.

20. The display device of claim 19, further comprising:
a fourth connection electrode disposed in the first source metal layer and electrically connecting the drain electrode of the first transistor, a drain electrode of the third transistor, and a drain electrode of the fifth transistor; and
a fifth connection electrode disposed in the first source metal layer and electrically connecting the initialization voltage line to a source electrode of the fourth transistor.
